(19) United States
(12) Patent Application Publication
(10) Pub. No.: US 2012/0125427 A1
(43) Pub. Date: May 24, 2012

(54) SOLAR CELL, AND METHOD FOR PRODUCING SAME

(75) Inventors: Jea Gun Park, Gyeonggi-Do (KR); Tae Hun Shim, Seoul (KR); Su Hwan Lee, Seoul (KR); Jin Heon Kim, Ulsan-Si (KR)

(73) Assignee: IUCF-HYU, Seoul (KR)

(21) Appl. No.: 13/260,335

(22) PCT Filed: Mar. 24, 2010
(86) PCT No.: PCT/KR2010/001791

§ 371 Date: Dec. 19, 2011

(30) Foreign Application Priority Data
Mar. 26, 2009 (KR) 10-2009-0025779

(51) Int. Cl. H01L 51/46; H01L 51/48; H01L 31/0224; B82Y 99/00

(52) U.S. Cl. 136/256; 136/252; 136/263; 438/98; 977/948; 257/E51.012

(57) ABSTRACT

Provided are a solar cell a solar cell having high light absorbance and power conversion efficiency and a method for producing the solar cell. The solar cell includes a substrate, a first electrode disposed on the substrate, a photoactive layer disposed on the first electrode, and a second electrode disposed on the photoactive layer. The photoactive layer includes an electron acceptor and at least two electron donors.

### CROSS-REFERENCE TO RELATED APPLICATION

This application claims priority to Korean Patent Application No. 10-2009-0025779 filed on Mar. 26, 2009 and all the benefits accruing therefrom under 35 U.S.C. §119, the contents of which are incorporated by reference in their entirety.

### BACKGROUND

The present disclosure relates to a solar cell and a method for producing the solar cell, and more particularly, to a solar cell having high light absorbance and power conversion efficiency and a method for producing the solar cell.

Solar cells are photoelectric conversion devices for converting solar energy into electric energy. Since solar energy is inexhaustible and eco-friendly, the importance of solar cells increases with time.

In the related art, single crystal or polycrystal silicon solar cells have been widely used. However, silicon solar cells have limitations such as high manufacturing costs, and it is difficult to manufacture silicon solar cells using flexible substrates. Therefore, much research has been conducted on organic solar cells as alternative.

Organic solar cells can be manufactured by methods such as a spin coating method, an inkjet printing method, a roll coating method, and a doctor blade method. That is, organic solar cells can be simply manufactured with low costs by coating large areas and forming thin films at a relatively low temperature. In addition, various kinds of substrates such as glass substrates and plastic substrates can be used to manufacture organic solar cells.

In addition, organic solar cells can be formed in various shapes such as a curved shape and a spherical shape like plastic products, and organic solar cells can be formed of bendable or foldable materials so that the organic solar cells can be easily carried. In this case, organic solar cells can be easily attached to clothes, bags, portable electric or electronic products. Furthermore, solar cells can be formed of polymer blend thin films that are highly transparent. In this case, solar cells can be attached to building or car glass for generating electricity without affecting the transparency of the glass. That is, such transparent solar cells can be used in more various fields than opaque silicon solar cells.

However, the power conversion efficiency and lifespan of such organic solar cells are not satisfactory for practical use. The power conversion efficiency of solar cells had been low at about 1% until the late 1990s. However, the power conversion efficiency of solar cells has been largely increased since 2000 owing to the improvement in polymer blend morphology.

The open circuit voltages of tandem solar cells are greater than the open circuit voltages of single-layer solar cells by about 0.4 V or a factor of about 2. In a study conducted by J. Xue et al (issued in 2004), sandwich type two tandem cells were connected in the form of ITO/CuPC/CuPC:C₆₀/C₆₀/PTCBI/Ag/m-MTDATA/CuPC/CuPC:C₆₀/C₆₀/BCP/Ag, and an opn circuit voltage of 1.03 V, a short circuit current of 9.7 mA/cm², and conversion efficiency of 5.7% (AM 1.5) were obtained (Appl. Phys. Lett. 85, 5757 (2004)).

However, such tandem solar cells are manufactured through complex processes because cells have to be stacked, and since upper cells in a stacked structure receive a small amount of light, optical loss of the tandem solar cells is high to lower the light absorbance of the tandem solar cells.

### SUMMARY

The present disclosure provides a solar cell that can be produced through a simple manufacturing process and has high light absorbance and power conversion efficiency, and a method for producing the solar cell.

In accordance with an exemplary embodiment, a solar cell includes: a substrate; a first electrode disposed on the substrate; a photoactive layer disposed on the first electrode; and a second electrode disposed on the photoactive layer, wherein the photoactive layer may include an electron acceptor and at least two electron donors.

Each of the electron donors may have a light absorption spectrum with one or more peak wavelengths, and at least one peak wavelength of one of the electron donors may be different from a peak wavelength of the other of the electron donors. In this case, one of the electron donors may have a peak wavelength in a short wavelength region, and the other of the electron donors may have a peak wavelength in a long wavelength region. The electron donors may have different band gap energies.

The photoactive layer may include: a donor layer including the electron donors; and an acceptor layer including the electron acceptor. The solar cell may further include an interfacial layer between the donor layer and the acceptor layer, wherein the interfacial layer may be formed by blending of the electron donors and the electron acceptor. The photoactive layer may be formed by blending of the electron acceptor and the electron donors.

The solar cell may further include a blocking layer between the photoactive layer and the second electrode.

The solar cell may further include: a hole migration layer between the first electrode and the photoactive layer; or an electron injection layer between the photoactive layer and the second electrode.

The first electrode may include a transparent conductive oxide layer, and the second electrode may include a metal. The transparent conductive layer may be formed of at least one material selected from ITO (indium tin oxide), FTO (fluorine-doped tin oxide), ZnO—(Ga2O3 or Al2O3), and SnO2-Sb2O3, and the metal may include one of gold, aluminum, copper, silver, nickel, an alloy thereof, a calcium/aluminum alloy, a magnesium/silver alloy, and an aluminum/lithium alloy.

The electron donors may include at least one selected from phthalocyanine, PtOEP (pt-octaethylporphyrin), P3HT (poly(3-hexylthiophene)), polysiloxane carbazole, polyaniline, polyethylene oxide, poly(1-methoxy-4-(O-disperse red 1))-2,5-phenylenevinylene, polyindole, polycarbazole, polypyridiazine, polyisothianaphthalene, polyphenylene sulfide, polyvinylpyridine, polythiophene, polyfluorene, polypyridine, and derivatives thereof.

The electron acceptor may include fullerene or a fullerene derivative.

The electron donors may include a polythiophene derivative and a phthalocyanine-based material, and the electron acceptor may include a fullerene derivative.

In accordance with another exemplary embodiment, there is provided a method for producing a solar cell having a photoactive layer between a first electrode and a second electrode, the method including: (a) forming a first electrode on a substrate; (b) forming a photoactive layer on the first electrode by using at least two electron donors and an electron acceptor; and (c) forming a second electrode on the photoactive layer.

The forming (b) of photoactive layer may include: preparing a photoactive layer material by blending the electron donors and the electron acceptor in an organic solvent; and coating the first electrode with the photoactive layer material by spin coating.

The forming (b) of the photoactive layer may include: forming a donor layer using the electron donors; and forming an acceptor layer on the donor layer by using the electron acceptor.

Each of the electron donors may have a light absorption spectrum with one or more peak wavelengths, and at least one peak wavelength of one of the electron donors may be different from a peak wavelength of the other of the electron donors.

The electron donors may have different band gap energies.

### BRIEF DESCRIPTION OF THE DRAWINGS

Exemplary embodiments can be understood in more detail from the following description taken in conjunction with the accompanying drawings, in which:

FIGS. 1 to 4 are sectional views schematically illustrating solar cells according to exemplary embodiments;

FIG. 5 is a view illustrating a solar cell produced according to an exemplary embodiment;

FIG. 6 is a graph showing light absorption wavelength regions of P3HT and CuPc;

FIG. 7 is a view showing ban gap energies of P3HT, CuPc, and PCBM;

FIG. 8 is a graph showing a light absorption wavelength region of an photoactive layer formed of a blend of P3HT and PCBM and a light absorption wavelength region of an photoactive layer formed of a blend of P3HT, CuPc, and PCBM;

FIG. 9 is a graph showing light absorption wavelength regions of P3HT, CuPc, and PCBM, respectively;

FIG. 10 is a graph showing a light absorption wavelength region of an photoactive layer formed of a blend of P3HT and PCBM in comparison with light absorption wavelength regions of photoactive layers formed by blending at least two of P3HT, CuPc, and PtOEP with PCBM;

FIG. 11 is a graph showing characteristics of the solar cell of FIG. 5; and

FIG. 12 is a graph showing characteristics of the solar cell of FIG. 5, short circuit current (Jsc) and power conversion efficiency (PCE) with respect to Wt % of CuPc.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration. Like reference numerals refer to like elements throughout. It will also be understood that when a layer, a film, a region or a plate is referred to as being ‘on’ another one, it can be directly on the other one, or one or more intervening layers, films, regions or plates may also be present. Further, it will be understood that when a layer, a film, a region or a plate is referred to as being ‘under’ another one, it can be directly under the other one, and one or more intervening layers, films, regions or plates may also be present. In addition, it will also be understood that when a layer, a film, a region or a plate is referred to as being ‘between’ two layers, films, regions or plates, it can be the only layer, film, region or plate between the two layers, films, regions or plates, or one or more intervening layers, films, regions or plates may also be present.

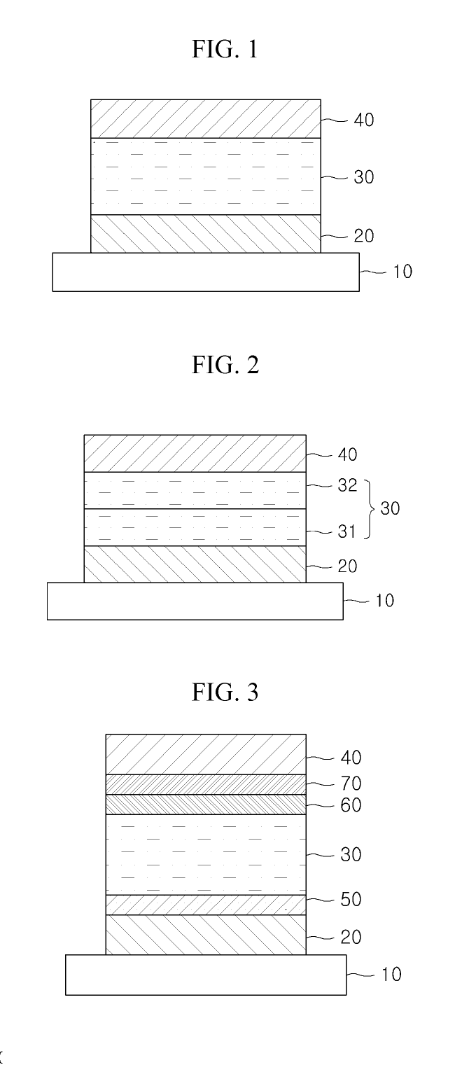

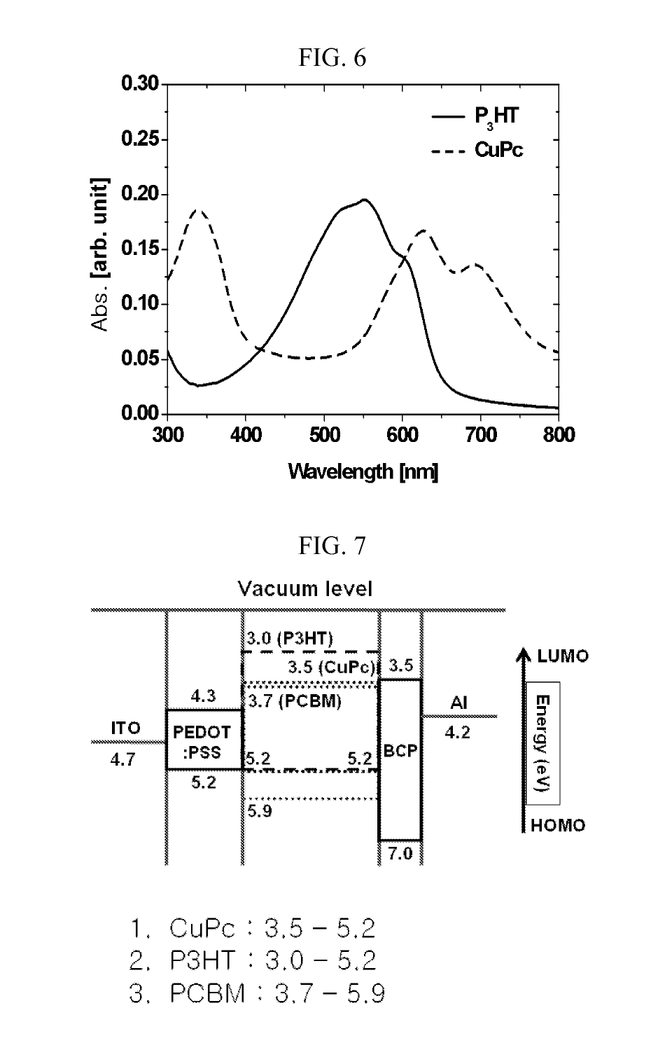

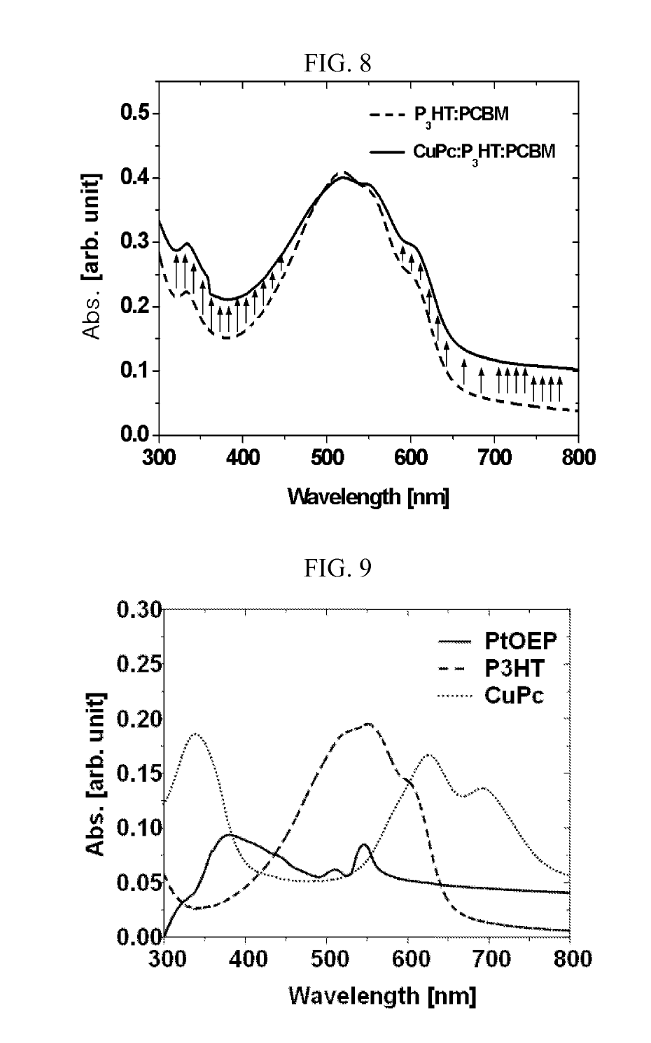

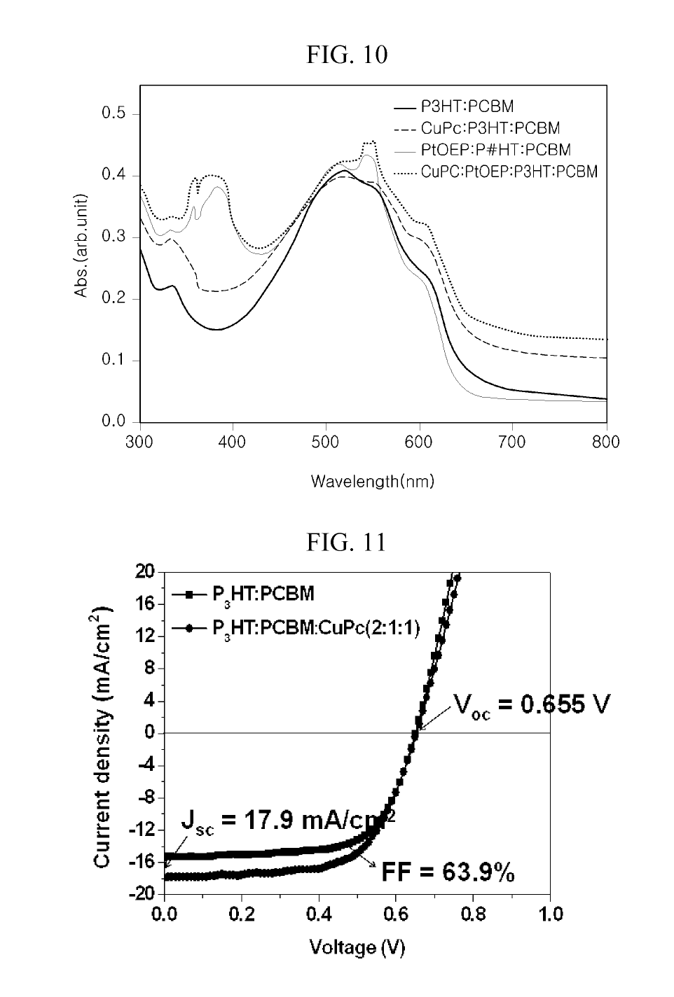

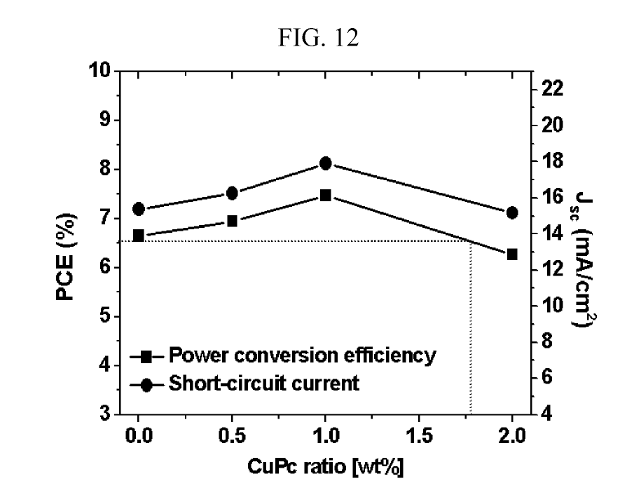

FIGS. 1 to 4 are sectional views schematically illustrating solar cells according to exemplary embodiments; FIG. 5 is a view illustrating a solar cell produced according to an exemplary embodiment; FIG. 6 is a graph showing light absorption wavelength regions of P3HT and CuPc; FIG. 7 is a view showing ban gap energies of P3HT, CuPc, and PCBM; FIG. 8 is a graph showing a light absorption wavelength region of an photoactive layer formed of a blend of P3HT and PCBM and a light absorption wavelength region of an photoactive layer formed of a blend of P3HT, CuPc, and PCBM; FIG. 9 is a graph showing light absorption wavelength regions of P3HT, CuPc, and PCBM, respectively; FIG. 10 is a graph showing a light absorption wavelength region of an photoactive layer formed of a blend of P3HT and PCBM in comparison with light absorption wavelength regions of photoactive layers formed by blending at least two of P3HT, CuPc, and PtOEP with PCBM; FIG. 11 is a graph showing characteristics of the solar cell of FIG. 5; and FIG. 12 is a graph showing characteristics of the solar cell of FIG. 5, short circuit current (Jsc) and power conversion efficiency (PCE) with respect to Wt % of CuPc.

Referring to FIG. 1, according to an exemplary embodiment, a solar cell includes a substrate 10, a first electrode 20, a photoactive layer 30, and a second electrode 40. The photoactive layer 30 includes an electron acceptors and electron donors. The electron donors may include two or more materials having different light absorption spectrums with different peak wavelengths. For example, one of the electron donors may has a peak wavelength in a short wavelength region, and the other may has a peak wavelength in a long wavelength region.

The substrate 10 may be any kind of transparent substrate. For example, the substrate 10 may be a transparent inorganic substrate such as a quartz substrate and a glass substrate; or a transparent plastic substrate formed of a material selected from the group consisting of polythylene terephthalate (PET), polyetylene naphthalate (PEN), polycarbonate (PC), polystyrene (PS), polypropylene (PP), polyimide (PI), polyether sulfone (PES), polyoxymethylene (POM), acrylonitrile/styrene (AS), and acrvlonitrile/butadien/styrene (ABS). The substrate 10 may have a transmittance of 70% or higher. For example, the substrate 10 may have a transmittance of 80% or higher.

Since light is incident on the photoactive layer 30 through the first electrode 20 after passing through the substrate 10, the first electrode 20 may be formed of a highly transparent material. For example, the first electrode 20 may be a transparent conductive oxide layer. For example, the first electrode 20 may be formed of a conductive material such as indium tin oxide (ITO), gold, silver, fluorine-doped tin oxide (FTO), ZnO—Ga₂O₃, ZnO—Al₂O₃, and SnO₂—Sb₂O₃. However, materials that can be used to form the first electrode 20 are not limited to the listed materials.

The photoactive layer 30 is disposed on the topside of the first electrode 20. The photoactive layer 30 includes an electron acceptor and two or more electron donors as described above. The electron donors may have different band gap energies. In this case, the electron donors have different light absorption spectrums having at least one peak wavelength. At least one peak wavelength of one of the electron donor may be different from a peak wavelength of the other of the electron donors. For example, if one of the electron donors has a peak wavelength in a short wavelength region (ultraviolet to blue wavelength region, 300 nm to 460 nm), the other of the electron donors may have a peak wavelength in a long wavelength region equal to greater than 460 nm such as a green wavelength region (460 nm to 550 nm) or a red wavelength region (600 nm to 750 nm).

In detail, the electron donors may include two or more conductive materials having light absorption spectrums with different peak wavelengths, or may include a blend of at least one conductive high molecular material and at least one conductive low molecular material. The term ‘high molecular material’ means a material having a molecular weight of approximately 10,000 or higher, and the term low molecular material' means a material having a molecular weight lower than approximately 10,000.

Examples of the conductive high molecular material include P3HT (poly(3-hexylthiophene)), polysiloxane carbazole, polyaniline, polyethylene oxide, poly(l-methoxy-4-(O-disperse red 1))-2,5-phenylenevinylene, polyindole, polycarbazole, polypyridiazine, polyisothianaphthalene, polyphenylene sulfide, polyvinylpyridine, polythiophene, polyfluorene, polypyridine, and derivatives thereof. Examples of the conductive low molecular material include copper pthalocyanine (CuPc) and Pt-octaethylporphyrin (PtOEP). The electron acceptor may include fullerene or fullerene derivative.

For example, in the case where the electron donors is formed of a blend of such materials, it may be necessary to select materials that can be well blended but does not react with each other. If materials that can react with each other to form a compound are selected, the photoactive layer 30 may not function or the conversion efficiency of the photoactive layer 30 may be lowered.

The second electrode 40 is formed of a material having high reflectance and low resistance so that the photoactive layer 30 can re-absorb light reflected from the second electrode 40. The second electrode 40 may include a metallic material. For example, the second electrode 40 may include: a metal such as magnesium (Mg), calcium (Ca), sodium (Na), potassium (K), titanium (Ti), indium (In), yttrium (Y), lithium (Li), aluminum (Al), silver (Ag), tin (Sn), and lead (Pb); or an alloy thereof. However, materials that can be included in the second electrode 40 are not limited thereto.

As shown in FIG. 2, alternatively, the photoactive layer 30 may include: a donor layer 31 formed by blending two or more electron donors; and an acceptor layer 32 including an electron acceptor. The solar cell shown in FIG. 2 is a low molecular solar cell. If the donor layer 31 absorbs light, excitons are generated. The electron donors included in the donor layer 31 may be two or more conductive low molecular materials having light absorption spectrums with different peak wavelengths. Examples of the conductive low molecular materials include copper pthalocyanine (CuPc) and Pt-octaethylporphyrin (PtOEP). Electrons separated from excitons are absorbed in the acceptor layer 32 and move in the acceptor layer 32. For this, the acceptor layer 32 includes a material having high electron affinity and migration. For example, the acceptor layer 32 may include a C60-C70 fullerene derivative. For example, the acceptor layer 32 may be formed of C60.

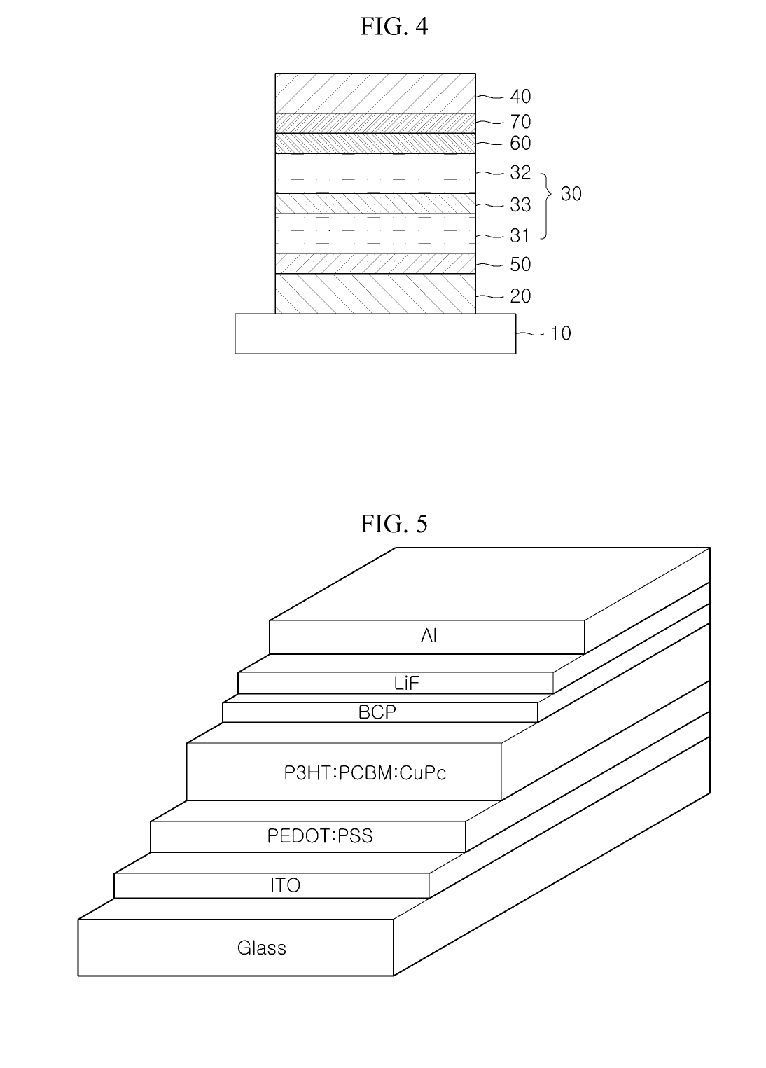

Referring to FIG. 3, according to another exemplary embodiment, a solar cell includes a substrate 10, a first electrode 20, a photoactive layer 30, and a second electrode 40 like the solar cell of the previous embodiment. In addition, the solar cell may further include a hole migration layer 50 between the first electrode 20 and the photoactive layer 30, and a blocking layer 60 and an electron injection layer 70 between the photoactive layer 30 and the second electrode 40. In other words, a stacked structure, such as a hole migration layer 50/photoactive layer 30, a photoactive layer 30/electron injection layer 70, a hole migration layer 50/photoactive layer 30/electron injection layer 70, or a hole migration layer 50/photoactive layer 30/blocking layer 60/electron injection layer 70, may be disposed between the first electrode 20 and the second electrode 40. Referring to FIG. 4, the photoactive layer 30 may include a donor layer 31 and an acceptor layer 32 as described above. In addition, the photoactive layer 30 may further include an interfacial layer 33 between the donor layer 31 and the acceptor layer 32. The interfacial layer 33 is disposed between the donor layer 31 and the acceptor layer 32 to facilitate separation of excitons into holes and electrons when the donor layer 31 generate excitons by absorbing light. The interfacial layer 33 may be formed by blending of the electron donor and the electron acceptor.

Holes separated from the photoactive layer 30 reach the first electrode 20 through the hole migration layer 50. For example, the hole migration layer 50 may be formed of a material in which holes can move smoothly. The hole migration layer 50 may include a conductive high molecular material such as PEDOT (poly(3,4-ethylenedioxythiophene), PSS (poly(styrenesulfonate), polyaniline, phthalocyanine, pentasen, polydiphenylacetylene, poly(t-butyl)diphenylacetylene, poly(trifluoromethyl)diphenylacetylene, Cu-Pc (copper-phthalocyanine), poly(bis trifluoromethyl)acetylene, polybis(t-butyldiphenyl)acetylene, poly(trimethylsilyl) diphenylacetylene, poly(carbazole)diphenylacetylene, polydiacetylene, polyphenylacetylene, polypyridineacetylene, polymethoxyphenylacetylene, polymethylphenylacetylene, poly(t-butyl)phenylacetylene, polynitrophenylacetylene, poly(trifluoromethyl)phenylacetylene, poly(trimethylsilyn)phenylacetylene, and derivatives thereof. One or a combination of the above-listed conductive high molecular materials may be included in the hole migration layer 50. However, the hole migration layer 50 is not limited thereto. For example, the hole migration layer 50 may include a PEDOT-PSS mixture.

The blocking layer 60 prevents holes and excitons from moving to the second electrode 40 from the photoactive layer 30 and recombining with each other. For example, the blocking layer 60 may be formed of a material such as bathocuproine (BCP) having a high HOMO (highest occupied molecular orbital) energy level.

The electron injection layer 70 facilitates injection of electrons separated from excitons into the second electrode 40. In addition, the electron injection layer 70 improves interfacial characteristics between the second electrode 40 and the blocking layer 60 or the photoactive layer 30. The electron injection layer 70 may include a material such as LiF and Liq.

The substrate 10, the first electrode 20, the photoactive layer 30, the second electrode 40, the donor layer 31, and the acceptor layer 32 are the same as those of the previous embodiment. Thus, descriptions thereof will not be repeated.

According to the above-described embodiments, the photoactive layer 30 of the solar cell includes an electron acceptor and at least two electron donors having light absorption spectrums with different peak wavelengths. Therefore, the solar cell can have a simple structure, high light absorbance, and high power conversion efficiency as compared with solar cells of the related art, particularly, tandem solar cells of the related art.

Next, a method for producing the solar cell will be described according to an embodiment.

According to an embodiment, the method includes (a) forming a first electrode on a substrate; (b) forming a photoactive layer on the first electrode by using at least two electron donors and an electron acceptor; and (c) forming a second electrode on the photoactive layer.

(b) The forming of the photoactive layer includes: preparing a photoactive layer material by blending the electron acceptor and the at least two electron donors in an organic solvent; and forming the photoactive layer material on the first electrode by a spin coating method. Each of the at least two electron donors has a light absorption spectrum with one or more peak wavelengths. At least one peak wavelength of one of the electron donors is different from a peak wavelength of the other of the electron donors. The electron donors have different band gap energies.

In the preparing of the photoactive layer material, two or more electron donor materials having different light absorption regions are blended with an electron acceptor material in the organic solvent. For example, the organic solvent may be chlorobenzene, benzene, chloroform, or tetrahydrofuran (THF). When the materials are blended, the concentrations of the materials may be adjusted in consideration of light absorption regions. Examples of the electron donor materials and the electron acceptor material have been listed above. For example, two or more electron donor materials selected from phthalocyanine-based materials such as copper phthalocyanine (CuPc) and zinc phthalocyanine (ZnPc) and conductive high molecular materials such as a polythiophene derivative may be blended with an electron acceptor material such as a fullerene derivative at a predetermined blending ratio for a predetermined time period.

Next, after forming the first electrode on the substrate, the prepared photoactive layer material is spin-coated on the first electrode and is annealed in a nitrogen atmosphere, so as to form the photoactive layer. Next, the second electrode is formed on the photoactive layer. In this way, the solar cell can be produced.

(b) The forming of the photoactive layer may include: forming a donor layer using the electron donors; and forming an acceptor layer on the donor layer by using the electron acceptor.

In addition, the method may further include: forming a hole migration layer between the forming of the first electrode and the forming of the photoactive layer; and forming a blocking layer and an electron injection layer between the forming of the photoactive layer and the forming of the second electrode. The forming of the hole migration layer, and the forming of the blocking layer and the electron injection layer are not limited. That is, methods known in the related art may be used to form the hole migration layer, the blocking layer, and the electron injection layer. The above-mentioned layers may be formed by a spin coating method. However, the present invention is not limited thereto. That is, other thin film forming methods can be used to form the layers.

Hereinafter, the solar cell and the method of producing the solar cell will be described in more detail with reference to experimental examples. The experimental examples should be considered in descriptive sense only and not for purpose of limitation.

### EXPERIMENTAL EXAMPLES

Production of Solar Cell for Evaluation

P3HT, CuPc, and PCBM were blended at a weight ratio of 2:1:1 in approximately 10 ml of chlorobenzene for at least 72 hours so as to prepare a photoactive layer material. If necessary, a filtering process might be performed after blending the P3HT, CuPc, and PCBM so as to remove unnecessary large particles from the photoactive layer material. Next, PEDOT-PSS and isopropyl alcohol (IPA) were blended at a weight ratio of 2:1 for at least 24 hours so as to prepare a hole migration layer material.

Thereafter, a first electrode was formed on a substrate by using indium tin oxide (ITO), and after cleaning the first electrode with a material such as acetone, the hole migration layer material was spin-coated on the first electrode at approximately 2000 rpm for approximately 60 seconds and was annealed in a nitrogen atmosphere at approximately 140° C. for approximately 10 minutes, so as to form a hole migration layer. Next, the photoactive layer material was spin-coated on the hole migration layer at approximately 1,000 rpm for approximately 60 seconds and was annealed in a nitrogen atmosphere at approximately 125° C. for approximately 10 minutes, so as to form a photoactive layer. Next, bathocuproine (BCP) was deposited on the photoactive layer to a thickness of approximately 12 nm by using a deposition device so as to form a blocking layer. Next, lithium fluoride (LiF) was deposited on the blocking layer to a thickness of approximately 0.5 nm, and aluminum (Al) was deposited to a thickness of approximately 80 nm, so as to form a second electrode. In this way, an evaluation solar cell as shown in FIG. 5 was made.

Measurement of Light Absorbance

As shown in FIGS. 6 and 7, P3HT absorbs light mainly in a wavelength region of approximately 350 nm to approximately 650 nm and has band gap energy of 3.0 eV to 5.2 eV, and CuPc absorbs light mainly in a wavelength region of approximately 300 nm to 400 nm and a wavelength region of approximately 550 nm to approximately 800 nm and has band gap energy of 3.5 eV to 5.2 eV. P3HT and CuPc were blended with PCBM (having band gap energy of 3.7 eV to 5.9 eV) at a ratio of P3HT:PCBM:CuPc=2:1:1, and the light absorbance of the blend was measured. Referring to the measurement result shown in FIG. 8, the light absorbance of the blend was increased in a wavelength region of approximately 300 nm to approximately 500 nm and a wavelength region of approximately 550 nm to approximately 800 nm. Therefore, short circuit current (Jsc) and power conversion efficiency may be increased by using the blend.

Results of another experimental example are shown in FIGS. 9 and 10.

FIG. 9 is a graph showing light absorption wavelength regions of P3HT, CuPc, and PCBM, respectively, and FIG. 10 is a graph showing a light absorption wavelength region of an photoactive layer formed of a blend of P3HT and PCBM in comparison with light absorption wavelength regions of photoactive layers formed by blending at least two of P3HT, CuPc, and PtOEP with PCBM. Curves shown in FIG. 10 were obtained by blending the above-mentioned materials at a weight ratio of P3HT=2: each of the other materials=1: for example, CuPc:PtOEP:PCBM:P3HT=1:1:1:2. As shown in FIG. 10, the light absorbances of the photoactive layers formed by blending at least two electron donors with PCBM are greater than the light absorbance of the photoactive layer formed of a blend of P3HT and PCBM. That is, power conversion efficiency may be increased in the case where a photoactive layer is formed by blending at least two electron donors with PCBM.

Measurement of Power Conversion Efficiency

Characteristics of solar cells may be evaluated based on open circuit voltage (Voc), short circuit current (Jsc), fill factor (FF), and efficiency. The open circuit voltage (Voc) is a voltage measured when light is irradiated on the solar cell in a state where an external electric load is not connected to the solar cell, that is, in a state where a current is zero. The short circuit current (Jsc) is a current generated when light is irradiated on a solar cell in a state where the solar cell is short-circuited, that is, in a state where a voltage is not applied to the solar cell. The fill factor (FF) is a ratio of the product of current and voltage of a solar cell to the product of open circuit voltage (Voc) and short circuit current (Jsc) of the solar cell. The open circuit voltage (Voc) and the short circuit current (Jsc) cannot be concurrent, and thus the fill factor (FF) is less than one. As the fill factor (FF) of a solar cell approaches one, the efficiency of the solar increases, and as the fill factor (FF) of a solar cell decreases, the resistance of the solar cell increases. Power conversion efficiency (ii) is defined by dividing the product of open circuit voltage (Voc), short circuit current (Jsc), and fill factor (FF) by the intensity of incident light (refer to Formula 1 below).

η=FF*(Jsc*Voc/(intensity of incident light))) [Formula 1]

Characteristics of the evaluation solar cell were measured to calculate the power conversion efficiency thereof. The measured characteristics of the evaluation solar cell were compared with those of a solar cell of the related art. The measured characteristics of the evaluation solar cell are shown in Table 1 below and FIG. 11. In Table 1, 0 wt % of CuPc denotes the solar cell of the related art, and 1 wt % of CuPc denotes the evaluation solar cell made according to an embodiment.

TABLE 1

| CuPc wt % | Voc | Jsc | Pmax | FF | Efficiency |
|---|---|---|---|---|---|
| 0 wt % | 0.655 | 15.36 | 0.150 | 0.661 | 6.648% |
| 1 wt % | 0.655 | 17.90 | 0.168 | 0.639 | 7.469% |

Referring to FIG. 11 and Table 1, if the case where P3HT, CuPc, and PCBM are blended is compared with the case of 0 wt % of CuPc (that is, the case where only P3HT and PCBM are blended), although the open circuit voltage (Voc) is not changed, the short circuit current (Jsc) is increased from 15.36 mA/cm² to 17.90 mA/cm², Pmax is increased from 0.150 to 0.168, and the fill factor (FF) is increased from 0.661 to 0.639. In addition, power conversion efficiency (PCE) calculated from the measured values by using Formula 1 is increased from 6.648% to 7.469%.

In addition, characteristic values were measured when the weight percent (wt %) of CuPc was 0, 0.5, 1.0, and 2.0, and then power conversion efficiency (PCE) was calculated, so as to evaluate the short circuit current (Jsc) and the power conversion efficiency (PCE) according to the weight concentration of CuPc. FIG. 12 and Table 2 show the short circuit current (Jsc) and the power conversion efficiency (PCE) with respect to the weight percent of CuPc.

TABLE 2

| CuPc wt % | Voc | Jsc | Pmax | FF | Efficiency |
|---|---|---|---|---|---|
| 0 wt % | 0.655 | 15.36 | 0.150 | 0.661 | 6.648% |
| 0.5 wt % | 0.635 | 16.25 | 0.156 | 0.673 | 6.946% |
| 1 wt % | 0.655 | 17.90 | 0.168 | 0.639 | 7.469% |
| 2.0 wt % | 0.655 | 15.17 | 0.141 | 0.631 | 6.266% |

Referring to Table 2, when the weight percent (wt %) of CuPc is 0.5 and 1.0, characteristics of a solar cell are improved as compared with characteristics of a related-art solar cell having an electron donor and an electron acceptor (that is, a solar cell including 0 wt % of CuPc). In addition, it can be understood that an optimal weight percent of CuPc is 1. Referring to FIG. 12, it can be understood that when the weight percent of CuPc is greater than 0 but equal to or less than 1.5, the power conversion efficiency (PCE) is higher than that of the related-art solar cell.

As described above, according to the embodiments, an electron acceptor and two or more electron donors having different light absorption wavelength regions are included in the photoactive layer of the solar cell. Therefore, the short circuit current (Jsc) of the solar cell can be increased, and thus the power conversion efficiency of the solar cell can be increased.

As described above, according to the embodiments, the photoactive layer is formed by blending the electron acceptor with the at least two electron donors having light absorption spectrums with different peak wavelengths, and thus the light absorbance of the photoactive layer can be increased. In this way, since optical loss can be minimized by a single-layer structure without using a multilayer structure, the solar cell can be produced through simple manufacturing processes with low costs. That is, the productivity of manufacturing processes can be improved to produce inexpensive solar cells.

Although the solar cell and the method for producing the solar cell have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A solar cell comprising:
a substrate;
a first electrode disposed on the substrate;
a photoactive layer disposed on the first electrode; and
a second electrode disposed on the photoactive layer,
wherein the photoactive layer comprises an electron acceptor and at least two electron donors.

2. The solar cell of claim 1, wherein each of the electron donors has a light absorption spectrum with one or more peak wavelengths, and at least one peak wavelength of one of the electron donors is different from a peak wavelength of the other of the electron donors.

3. The solar cell of claim 2, wherein one of the electron donors has a peak wavelength in a short wavelength region, and the other of the electron donors has a peak wavelength in a long wavelength region.

4. The solar cell of claim 1, wherein the electron donors have different band gap energies.

5. The solar cell of claim 1, wherein the photoactive layer comprises:
a donor layer comprising the electron donors; and
an acceptor layer comprising the electron acceptor.

6. The solar cell of claim 5, further comprising an interfacial layer between the donor layer and the acceptor layer, wherein the interfacial layer is formed by blending of the electron donors and the electron acceptor.

7. The solar cell of claim 1, wherein the photoactive layer is formed by blending of the electron acceptor and the electron donors.

8. The solar cell of claim 1, further comprising a blocking layer between the photoactive layer and the second electrode.

9. The solar cell of claim 1, further comprising:
a hole migration layer between the first electrode and the photoactive layer; or
an electron injection layer between the photoactive layer and the second electrode.

10. The solar cell of claim 1, wherein the first electrode comprises a transparent conductive oxide layer, and the second electrode comprises a metal.

11. The solar cell of claim 10, wherein the transparent conductive layer is formed of at least one material selected from ITO (indium tin oxide), FTO (fluorine-doped tin oxide), ZnO—(Ga₂O₃ or Al₂O₃), and SnO₂—Sb₂O₃, and the metal comprises one of gold, aluminum, copper, silver, nickel, an alloy thereof, a calcium/aluminum alloy, a magnesium/silver alloy, and an aluminum/lithium alloy.

12. The solar cell of claim 1, wherein the electron donors comprise at least one selected from phthalocyanine, PtOEP (pt-octaethylporphyrin), P3HT (poly(3-hexylthiophene)), polysiloxane carbazole, polyaniline, polyethylene oxide, poly(l-methoxy-4-(O-disperse red 1))-2,5-phenylenevinylene, polyindole, polycarbazole, polypyridiazine, polyisothianaphthalene, polyphenylene sulfide, polyvinylpyridine, polythiophene, polyfluorene, polypyridine, and derivatives thereof.

13. The solar cell of claim 1, wherein the electron acceptor comprises fullerene or a fullerene derivative.

14. The solar cell of claim 1, wherein the electron donors comprise a polythiophene derivative and a phthalocyanine-based material, and the electron acceptor comprises a fullerene derivative.

15. A method for producing a solar cell having a photoactive layer between a first electrode and a second electrode, the method comprising:
(a) forming a first electrode on a substrate;
(b) forming a photoactive layer on the first electrode by using at least two electron donors and an electron acceptor; and
(c) forming a second electrode on the photoactive layer.

16. The method of claim 15, wherein the forming (b) of photoactive layer comprises:
preparing a photoactive layer material by blending the electron donors and the electron acceptor in an organic solvent; and
coating the first electrode with the photoactive layer material by spin coating

17. The method of claim 15, wherein the forming (b) of the photoactive layer comprises:
forming a donor layer using the electron donors; and
forming an acceptor layer on the donor layer by using the electron acceptor.

18. The method of claim 15, wherein each of the electron donors has a light absorption spectrum with one or more peak wavelengths, and at least one peak wavelength of one of the electron donors is different from a peak wavelength of the other of the electron donors.

19. The method of claim 15, wherein the electron donors have different band gap energies.
